(19) United States
(12) Patent Application Publication
(10) Pub. No.: US 2013/0044435 A1
(43) Pub. Date: Feb. 21, 2013

(54) SYSTEM IN PACKAGE, PRINTED CIRCUIT BOARD PROVIDED WITH SUCH SYSTEM IN PACKAGE

(71) Applicant: Stijn Vandebril, Kessel-Lo (BE)

(72) Inventor: Stijn Vandebril, Kessel-Lo (BE)

(73) Assignee: OPTION, Leuven (BE)

(21) Appl. No.: 13/497,890

(22) PCT Filed: Sep. 24, 2010
(86) PCT No.: PCT/EP2010/064199

§ 371 Date: Nov. 8, 2012

(30) Foreign Application Priority Data
Sep. 24, 2009 (EP) 09171261.2

(51) Int. Cl. H05K 7/06; H05K 7/20

(52) U.S. Cl. 361/720; 361/767

(57) ABSTRACT

System in package including a substrate having a first external layer including a first conductive patterned layer and being externally accessible for electrically connecting the system in package to an external electric circuit and a second internal layer including a second conductive patterned layer and being covered by the first layer and electronic devices provided on the substrate and electrically connected to external contact pads of the first conductive patterned layer. The devices and the first and second conductive patterned layer being electrically connected to form an internal electric circuit electronically connected to the external electric circuit, the first and the second layer being adjacently positioned, the electronic devices being enclosed in an overmould compound. At least one of the devices is electrically connected to at least one hidden contact pad of the second conductive patterned layer which is accessible after removal of a removable strip of the first layer.

### TECHNICAL FIELD

The present invention relates to a system in package according to the preamble of the first claim.

The invention also relates to a printed circuit board comprising a printed circuit board substrate on which an electrical circuit is provided electrically connected to such a system in package.

### BACKGROUND ART

Such systems in package are already well-known to the person skilled in the art. US-A1-2007/0273014 for example describes a system in package comprising at least a first external and a second internal layer respectively provided with a first and a second conductive patterned layer. The first conductive patterned layer is externally accessible for electrically connecting the system in package to an electric circuit whereas the second conductive patterned layer is covered by the first external layer. The system in package further comprises electronic devices provided on the substrate and electrically connected to external contact pads of the first layer. The external contact pads are provided to be electrically connected to an electric circuit provided on a printed circuit board. The system in package is attached to the printed circuit board by soldering the external contact pads to the electric circuit provided on the printed circuit board. The devices and the first and the second conductive patterned layers are provided to be electronically connected to the external electric circuit. It is however not possible in such system in packages to access the second conductive patterned layer, for example for accessing unused functionalities, without an increased risk of damaging the overall circuitry of the system in package. The first and the second layer are adjacently positioned and the electronic devices are enclosed in an overmould compound.

### DISCLOSURE OF THE INVENTION

It is therefore an aim of the present invention to provide a system in package in which additional contact pads of the second conductive patterned layer can be made available.

This is achieved in the present invention with the technical features of the characterising part of the first claim.

Thereto, at least one of the devices is electrically connected to at least one hidden contact pad of the second conductive patterned layer which is accessible, preferably only accessible, after removal of a removable strip of the first layer.

Such a system in package offers the possibility to provide additional functionalities to a system in package which can be uncovered depending on the application in which the system in package will be used. This way the versatility of the system in package is increased.

Since to make the hidden contact pad accessible only a strip needs to be removed from the first layer, the distance from the first layer to the hidden contact pad is limited and electric contact with the formerly hidden contact pad after removal of the strip can for example be made by simply covering the contact pad with solder paste or using known methods.

The first and the second layer are adjacently positioned. In such a system in package, the hidden contact pad of the second conductive patterned layer is positioned directly under the strip of the first layer.

In the context of the current application a contact pad is defined as a conductive member provided to be in electrical contact with an external electric circuit and which is a conductive part of an electrically conductive path providing an electrical connection to one of the electronic devices of the system in package. The contact pad is located at an end part of the conductive path which is distal from an opposing end part of the conductive path providing an electrical connection to one of the electronic devices of the system in package.

The strip is indicated on the first layer and is a planar object, oriented in the plane of the first layer and may have the form of a planar piece of the first layer. In preferred embodiments of the system in package according to the current invention, the thickness of the strip and the thickness of the first layer are the same such that by removing the strip of the first layer, objects, such as for example the hidden contact pad, beneath the first layer become accessible.

In preferred embodiments of the system in package according to the current invention, the system in package is planar and the first layer is a top layer of the system in package. Such systems in packages can be connected to printed circuit boards having contacts provided to make contact with the external contact pads of the first conductive patterned layer by, for example, pressing the system in package on the printed circuit board with the external contact pads electrically contacting the corresponding contacts provided on the printed circuit board.

In preferred embodiments of the system in package according to the present invention, the strip is provided to be peeled off the system in package. Such a removal of the strip off the remainder of the first layer has been found sufficiently reliable to avoid an unwanted accessibility of the hidden contact pad while nevertheless allowing an accessibility of the hidden contact pad when required.

In preferred embodiments, the hidden contact pad is a debugging pad. By providing such a hidden contact pad, the working of at least one of the devices can be checked, for example by measuring the voltages at the debug pad, even without necessarily having to interfere with the working of the remainder of the system in package, allowing for example to debug the working of the system in package after completion of the system in package. Thereto, the removable strip of the first layer is removed such that the hidden contact pad is sufficiently uncovered to allow, for example, a voltage measurement. In the prior art, the correct working of the individual electronic devices and/or the correct working of several cooperating electronic devices can not be checked after completion of the system in package since the electronic devices are often completely integrated into the system in package, by for example an overmould compound, without thereafter offering any possibility for checking the working of the electronic devices. The working of at least one of the electronic devices in the prior art can therefore only be checked when the system in package is not fully completed and when the electronic devices are not yet completely integrated into the system in package without offering any opportunity for checking the working of the electronic device, for example before the overmould compound is applied onto the electronic devices. Debugging the system in package according to the prior art after completion of the system in package is therefore no longer possible.

Although it is possible to provide for additional external contact pads in the finished system in package which allow to check the working of at least one of the electronic devices, such additional external contact pads often remain unused when the system in package is, for example, commercially applied in consumer products and may lead to unwanted noise or even signals which disturb the working of the system in package in the consumer products.

In preferred embodiments, the removable strip is one of the external contact pads of the first layer having a different functionality from the hidden contact pad. Such a configuration, for example, offers the possibility to choose either the functionality offered by the external contact pad or alternatively the functionality offered by the hidden contact pad.

In further preferred embodiments, at least one of the devices is electrically connected to a second hidden contact pad of the second layer, in addition to the hidden contact pad discussed above, which is, preferably only, accessible after removal of the removable strip of the first layer, the additional hidden contact pad having the same functionality as the external contact pad of the removable strip. Such a configuration allows for example that an optional functionality of an electronic device can be covered when remaining unused, but can be uncovered when the application of the system in package demands so without losing the functionality of the external contact pad which is removed.

The invention also relates to a printed circuit board comprising a printed circuit board substrate on which an electric circuit is provided electrically connected to a system in package according to the invention.

In preferred embodiments of the printed circuit board according to the invention, at least one of the external contact pads is a soldering pad having a predetermined size for heat dissipation and the system in package is soldered to the printed circuit board substrate by means of the soldering pad and the printed circuit board substrate comprises one or more through holes in the area of the soldering pad for allowing flux gasses resulting from soldering to escape. Such printed circuit boards have the advantage that, since the flux gasses resulting from soldering can more easily escape through the through holes, the risk of void formation by the flux gasses resulting from soldering is substantially reduced, resulting in a better and more robust attachment of the system in package to the printed circuit board. Moreover it has been found that soldering material, especially soldering paste, will spread better over the soldering pads of the system in package such that the system in package will collapse more to the printed circuit board leading to a decreased thickness of the overall printed circuit board.

In more preferred embodiments of the printed circuit board according to the invention, the through-hole is provided at the centre of the soldering pad. Such a more symmetric positioning further increases the escape of flux gasses resulting from soldering, leading to a further improved attachment of the system in package to the printed circuit board.

The invention also relates to a method for attaching a system in package having at least one external soldering pad by soldering the soldering pad onto a printed circuit board substrate such that the system in package is electrically connected to an electrical circuit provided on the printed circuit board substrate, wherein prior to soldering, one or more through holes are provided in the printed circuit board substrate in the area where the soldering pad is to be soldered to the printed circuit board. As described above in the resulting printed circuit boards, the flux gasses resulting from soldering can more easily escape through the through holes, the risk of void formation by the flux gasses resulting from soldering becoming substantially reduced, resulting in a better and more robust attachment of the system in package to the printed circuit board. Moreover it has likewise been found that soldering material, especially soldering paste, will spread better over the soldering pads of the system in package such that the system in package will collapse more to the printed circuit board leading to a decreased thickness of the overall printed circuit board.

### BRIEF DESCRIPTION OF THE DRAWINGS

The invention will be further elucidated by means of the following description and the appended drawings.

FIG. 1 shows a cross-section of a system in package according to the present invention.

FIG. 2 shows the cross-section according to FIG. 1 after removal of a removable strip of the first layer.

FIG. 3 shows a detail of a bottom view of the system in package according to the invention.

FIG. 4 shows the bottom view according to FIG. 3 with the removable strip removed from the system in package.

FIG. 5 shows a top view of a printed circuit board with indications for the desired location of the system in package shown in FIGS. 2 and 3.

FIG. 6 shows a top view of a pattern for applying solder paste onto the printed circuit board shown in FIG. 5.

FIG. 7 shows a top view of a different pattern for applying solder paste onto a printed circuit board with no or only a few through holes provided.

FIG. 8 shows a recommended reflow profile for soldering a system in package to a printed circuit board.

FIG. 9 shows a side view of a printed circuit board provided with a system in package and SMD which was used to obtain the data of FIG. 8.

### MODES FOR CARRYING OUT THE INVENTION

The present invention will be described with respect to particular embodiments and with reference to certain drawings but the invention is not limited thereto but only by the claims. The drawings described are only schematic and are non-limiting.

Furthermore, the terms first, second, third and the like in the description and in the claims, are used for distinguishing between similar elements and not necessarily for describing a sequential or chronological order. The terms are interchangeable under appropriate circumstances and the embodiments of the invention can operate in other sequences than described or illustrated herein.

Moreover, the terms top, bottom, over, under and the like in the description and the claims are used for descriptive purposes and not necessarily for describing relative positions. The terms so used are interchangeable under appropriate circumstances and the embodiments of the invention described herein can operate in other orientations than described or illustrated herein.

The term “comprising”, used in the claims, should not be interpreted as being restricted to the means listed thereafter; it does not exclude other elements or steps. It needs to be interpreted as specifying the presence of the stated features, integers, steps or components as referred to, but does not preclude the presence or addition of one or more other features, integers, steps or components, or groups thereof. Thus, the scope of the expression “a device comprising means A and B” should not be limited to devices consisting only of components A and B. It means that with respect to the present invention, the only relevant components of the device are A and B.

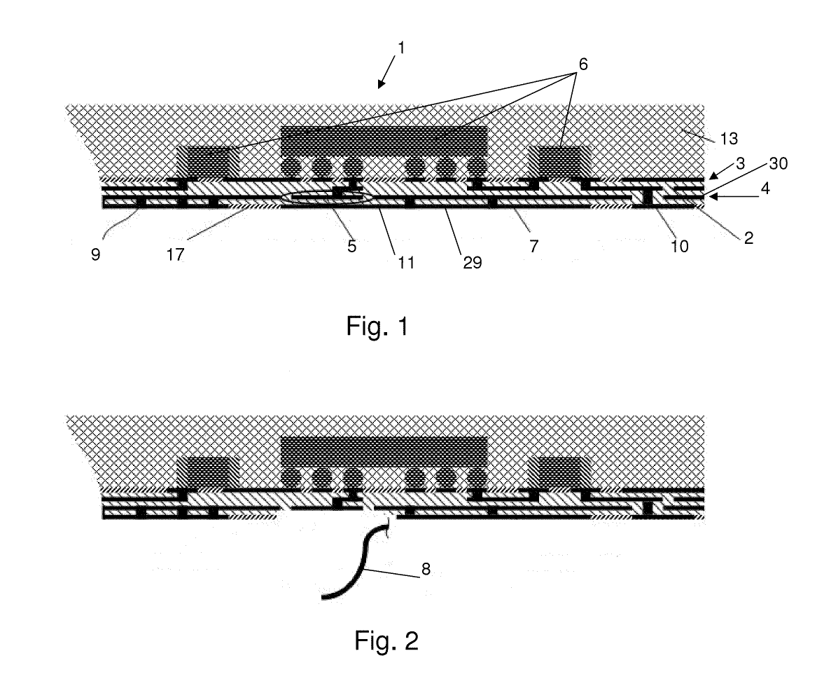

FIG. 1 shows a cross-section of a system in package 1 according to the invention. The shown system in package 1 comprises a substrate 4. On the substrate 4 a first external layer 2 comprising a first conductive patterned layer 29 is provided. The first conductive patterned layer 29 is externally accessible for electrically connecting the system in package 1 to an electric circuit. External contact pads 7 are provided in the first layer 2. The system in package 1 further comprises a second internal layer 3 provided with a second conductive patterned layer 30 which is covered by the first layer 2. Electronic devices 6 are provided on the substrate 4 and are electrically connected to the external contact pads 7, 9, 10.

By electrically connecting the system in package 1 to the electric circuit through the first conductive patterned layer 30, the different electronic devices 6 are functionally employed into the electric circuit. By providing predetermined electronic devices 6 which are interconnected internally by the second internal conductive patterned layer 30 and/or the first conductive patterned layer 29 the system in package 1 can be designed to perform a predetermined electrical functionality by bundling the electrical functionality of the different electronic devices 6. This for example allows providing an electrical functionality into a single package, the system in package 1, such that this functionality can directly be employed into an electric circuit. This way, electrical functionalities can be bundled into relatively small modules and can for example be produced on a relatively large scale.

FIG. 1 for example shows three electronic devices 6 interconnected by the second conductive patterned layer 30 such as to perform a predetermined electrical functionality. The predetermined electrical functionality of the electronic devices 6 and the electrical functionality resulting from the interconnection of the second conductive patterned layer 30 are not critical for the invention and can be determined by the person skilled in the art in function of the intended use of the system in package 1. Also the number of the electronic devices 6 is not critical for the invention and can also be determined by the person skilled in the art in function of the desired electrical functionality offered by the system in package 1. For example the system in package 1 may comprise a central processing unit, a memory possibly combined with passive components such as resistors, inductors and capacitors which, when appropriately electrically interconnected, can provide a fully operational computer system in a single package.

Every type of electronic device 6 can be used to form the system in package 1, but often the electronic devices 6 used in the system in package 1 are integrated circuits. Using integrated circuit 6 moreover has the advantage that the volume of the system in package 1 can be reduced.

The first layer 2 is often provided to be attached to a further substrate, for example but not limited thereto a printed circuit board, and thereto is often, as shown in FIG. 1, as flat as possible. This is however not critical for the invention and the first layer can also have another shape depending on the way the system in package 1 will be mounted into its final location.

The electronic devices 6 provided on the substrate 4 are in FIG. 1 more specifically provided on the second internal layer 3. This is however not critical for the invention and at least one of the electronic devices 6 can also be provided on the first layer 2. However, when providing all electronic devices 6 on the second layer 3, the location of the electronic devices 6 interferes less with the provision of the first layer 2. Especially when the system in package 1 is mounted to a further substrate at the first layer 2, it has been found that the electronic devices 6 are better provided on the second layer 3 such that they interfere less with the mounting of the system in package 1 to the further substrate.

FIG. 1 shows that the second layer 3 and the devices 6 provided thereon are covered with an overmould compound 13 for example ceramic material. Such an overmould compound provides the system in package 1 with an increased robustness by protecting the second layer 3 and the electronic devices 6.

FIG. 1 shows three external contact pads 7 lying next to each other. However, the location and the number of the external contact pads 7 are not critical for the invention and can be adapted by the person skilled in the art. For example more or less external contact pads 7 can be provided and/or the external contact pads 7 can be provided on different locations.

One of the external contact pads 7 can be provided to be a ground pad 9 and therefore be provided to be electrically connected to a ground signal. However one of the external contact pads 7 can also be provided as a signal pad 10 and therefore be provided to be electrically connected to a signal different from the ground signal. This is however not critical for the invention.

One of the external contact pads 7 can, possibly but not necessarily in addition to being a ground pad 9 or a signal pad 10, be a soldering pad 11. The soldering pad 11 is provided to be soldered to the further substrate, such as for example a printed circuit board and thereto preferably has a predetermined size for dissipating heat caused by soldering the soldering pad 11 to the further substrate.

The substrate 4 shown in FIG. 1 is a land grid array substrate in which the external contact pads 7 are substantially flat and form an array in one of the external surfaces of the system in package 1, more in particular a mounting surface 17 to which the system in package 1 will be mounted to a further substrate. This is however not critical for the invention and the substrate 4 may also be, for example, a pin grid array in which the external contact pads 7 are in the form of pins extending from the mounting surface 17, ball grid array in which the external contact pads 7 are in the form of balls, etc. In addition, also the provision of the external contact pads 7 in the form of an array is not critical for the invention and the external contact pads 7 can also be, for example, randomly distributed in the external surface 17 of the system in package 1.

FIG. 1 also shows a hidden contact pad 5 in the second layer 3. The hidden contact pad 5 is similar to the external contact pads 7 with the differences of being provided in the second layer 3 and being hidden by at least part of the first layer 2 such that it is only accessible after removal of a removable strip 8 of the first layer 2.

FIG. 2 shows the cross-section according to FIG. 1 after removal of a removable strip 8 of the first layer 2. The removable strip 8 shown in FIG. 2 is a part of one of the external contact pads 7, more precisely the ground pad 9, of the first layer 2. This is however not critical for the invention and other parts of the first layer 2, not being an external contact pad 7, can also be the removable strip 8. Moreover, also part of a signal pad 10 or a soldering pad 11 not being a signal pad 10 or soldering pad 11 could be the removable strip 8. The removable strip 8 can even comprise a complete external contact pad 7. When only part of the external contact pad 7 is part of the removable strip 8, the remaining part of the external contact pad 7, after removal of the removable strip 8, can still be used as, for example, signal pad 10, ground pad 9 and/or soldering pad 11.

The removable strip 8 can be removed by, for example, scratching away the removable strip 8, pulling away, peeling off the removable strip 8, chemically removing the removable strip 8, etc. Preferably, the removable strip 8 is removed by scratching, pulling away or peeling off the removable strip 8, since such a removal can easily be performed without using further equipment and without substantial mechanical provisions to the system in package 1.

The revealed hidden contact pad 5 can have any functionality known to the person skilled in the art. The hidden contact pad 5 can for example be a soldering pad and/or can have an electrical functionality such as for example being a ground pad, a signal pad, etc. as is described for the external contact pad 7.

In case for example the removable strip 8 is one of the external contact pads 7, the functionality of the hidden contact pad 5 can be different from the functionality of the removed external contact pad 7. Such that when, for example, the removed external contact pad 7 was a ground pad 9, the hidden contact pad 5 can perform the function of a signal pad or when the removed external contact pad 7 was a signal pad 10, the hidden contact pad 5 can also be a signal pad but for a different electrical signal and/or for a different electrical functionality, etc.

This way it is for example possible to provide different electronic alternatives on a single system in package 1. For example, a system in package 1 can be provided with two alternative electronic devices. The external contact pad 7 can for example be configured such as to direct a first of these electronic devices, whereas the hidden contact pad 5 is provided to direct a second of these electronic devices, alternative to the first electronic device. This way, the system in package 1 by default offers the possibility to use the first electronic device but can be configured to use the second electronic device by removing the external contact pad 7 and instead using the hidden contact pad 5. The first electronic device for example is a WIFI transmitter and the second electronic device for example is an UMTS transmitter.

In a further example, in case the removable strip 8 is one of the external contact pads 7 and the external contact pad 7 has a different functionality from the hidden contact pad 5, at least one of the devices 6 is electrically connected to an additional hidden contact pad 5 in the second layer 3 which is only accessible after removal of the removable strip 8 of the first layer 2, the additional hidden contact pad 18 can have the same functionality as the external contact pad 7 of the removable strip 8. Such a configuration allows that although the whole external contact pad 7 is part of the removable strip 8, the functionality of the external contact pad 7 is nevertheless not lost when removing the external contact pad 7. However, the hidden contact pad 18 can also have a different functionality from the external contact pad 7 and as the initial contact pad 5 such as to offer further functionalities to the system in package 1.

Although one additional hidden contact pad 18 can be sufficient, the number of hidden contact pads 18 is not essential for the invention and more than one additional contact pad 18 can be provided such as for example two, three, four, etc.

In a further example it is for example also possible that more than one external contact pads 7 are part of the removable strip 8.

It is for example possible that the removable strip 8 comprises more than one external contact pad 7 which cover only a single hidden contact pad 18. Such a configuration for example allows that unnecessary contact pads, which are for example often used, can be removed and replaced in specific uses of the system in package 1.

The number of external contact pads 7, as a whole or in part, which are part of the removable strip 8, the number of hidden contact pads 5 and/or their functionalities combined and/or individually are not critical for the invention and can be determined by the person skilled in the art depending on the specific envisioned use of the system in package 1.

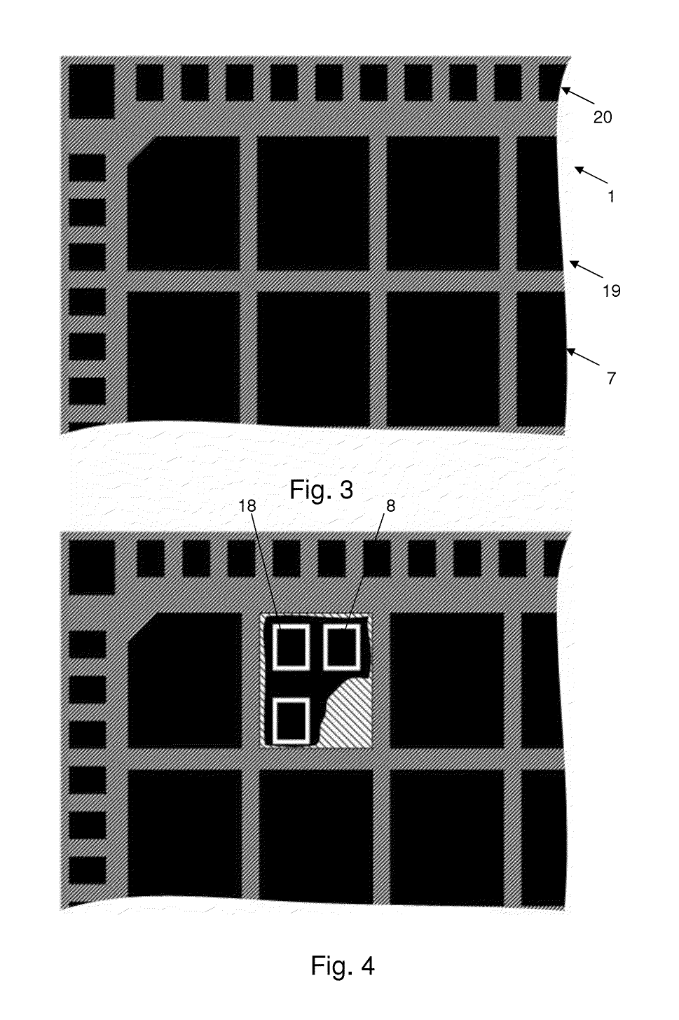

FIG. 3 shows a detail of a bottom view of the system in package 1 and shows eight central external contact pads 19 surrounded by a series of surrounding contact pads 20. The surrounding external contact pads 20 are provided as signal pads and the central external contact pads are provided as ground contact pads and solder contact pads. The configuration of the different contact pads 7 is, as mentioned above, however not critical for the invention and can be altered by the person skilled in the art depending on the envisioned use of the system in package 1.

The system in package 1 in this case is a quad flat package, more precisely a quad flat package no lead. Specifically, the land grid array substrate, as discussed above, is also shown. However, other types of systems in package 1 are nevertheless possible and can be determined by the person skilled in the art.

The upper left external contact pad 7 has part of one of its corners removed for indicating a predetermined orientation of the system in package 1. This allows the system in package 1 to be correctly electrically connected to an electrical circuit. The form and shape of the means which allow the system in package 1 to be oriented, in this case the removed corner, are not critical and any other indication can be used such as for example a mark on the substrate 4, etc.

FIG. 4 differs from FIG. 3 in that one of the external contact pads 7 is broken away revealing three hidden contact pads 5. In case the external contact pad 7 broken away was a soldering pad and was not provided to be a signal pad or ground pad, the soldering functionality in such a case could be taken over by, for example, the adjacent external contact pads 7 or one of the revealed hidden contact pads 5.

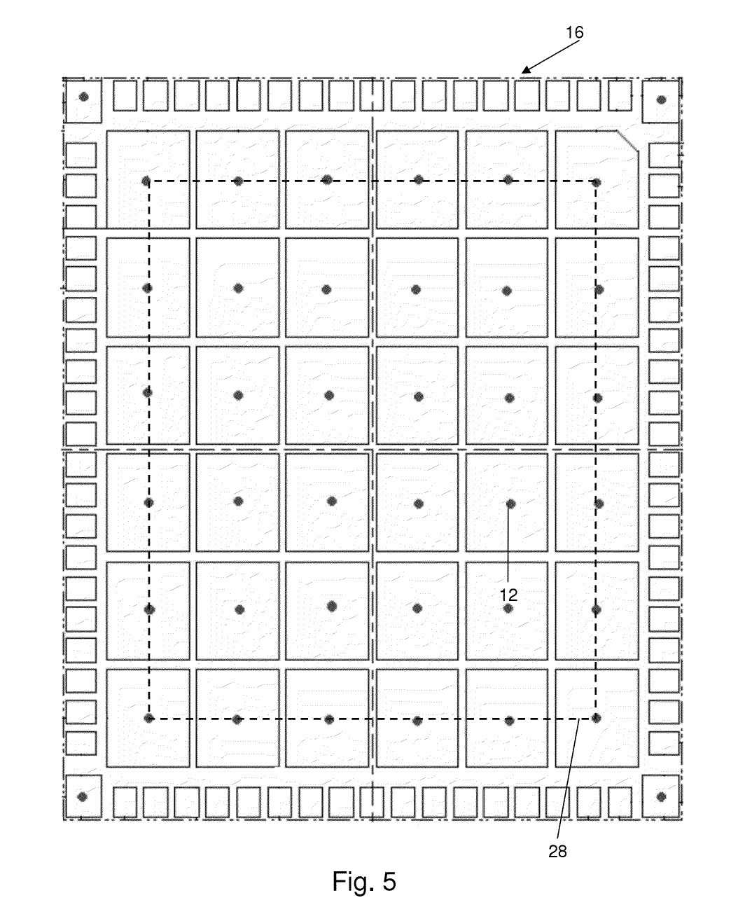

FIG. 5 shows a top view of a printed circuit board 16 with indications for the desired location of the system in package shown in FIGS. 2 and 3, also known under the name of a land pattern. The printed circuit board 16 comprises a printed circuit board substrate on which an electrical circuit is electrically provided to be electrically connected to the system in package 1. The electrical circuit is however not shown in the figures.

The system in package 1, or any other system in package, can be soldered to the printed circuit board substrate by means of at least one soldering pad 11. The printed circuit board substrate shown in FIG. 5 comprises a single through-hole 12 in the centre of the area of where such a soldering pad 11 will be provided. Such a through-hole 12 allows flux gasses resulting from soldering to escape. Although the through-hole 12 is provided in the centre of the area of where the soldering pad 11 will be provided, the through-hole 12 can also be provided at any other location in the area of where the soldering pad 11 will be provided. Also, although only a single through-hole 12 is provided, more than one through-hole 12 can be provided in the area where the soldering pad 11 will be located.

Although FIG. 5 shows that a through-hole 12 is provided on the location of each of the soldering pads 11, this is not critical for the invention and some through holes 12 may be omitted. However, it has been found by the inventor that a symmetrical location of the through holes on the printed circuit board offers an improved effect of the escape of the gasses resulting from the soldering. For example, with respect to FIG. 5, omitting the through holes 12 at the four corner contact pads 7 and/or only providing through holes 12 at the contact pads 28 delimiting the field of contact pads 7, in the case of FIG. 5, twenty contact pads.

The through holes 12 preferably have a diameter of between 0.5 and 0.9 mm, more preferably between 0.6 and 0.8 mm and most preferably of 0.7 mm. Such diameters have been found to decrease the risk that leakage of soldering material, particularly solder paste, occurs through the through-hole 12.

Preferably, the through holes 12 are non plated which have been found to avoid leakage of soldering material, more in particular soldering paste.

Accordingly a system in package 1, not limited to the system in package 1 according to the invention, can be attached to a printed circuit board by soldering a soldering pad 11 of the system in package 1 onto the printed circuit board substrate such that the system in package 1 is electrically connected to an electrical circuit provided on the printed circuit board substrate. To obtain the desired escape of gasses resulting from the soldering, prior to soldering, one or more of through holes 12, as mentioned above, are provided in the printed circuit board substrate in the area where the soldering pad 12 is to be soldered to the printed circuit board 16.

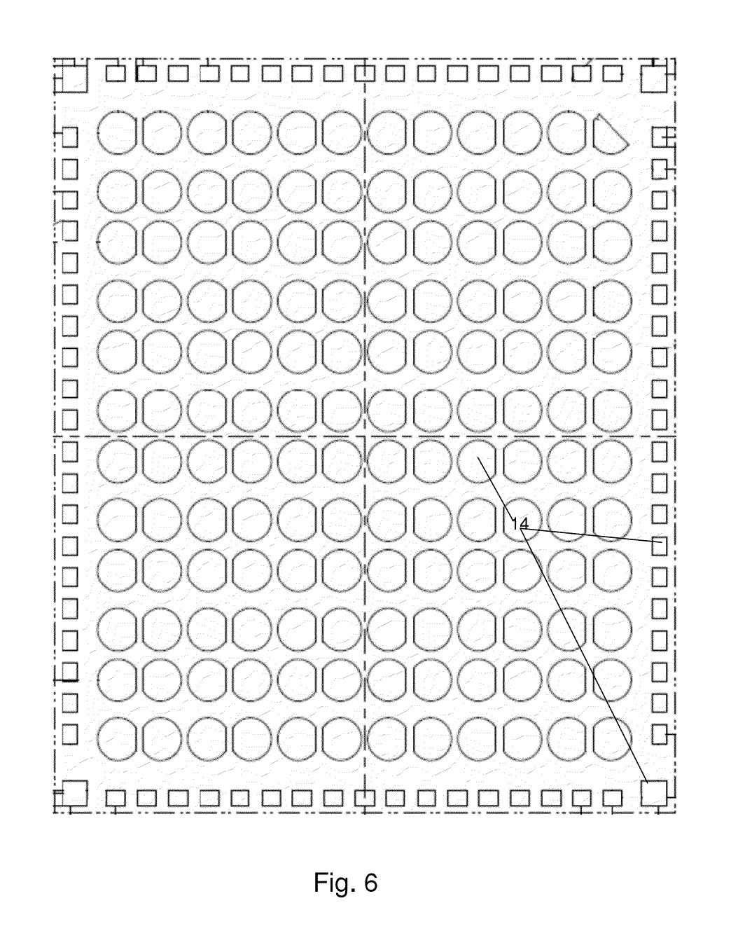

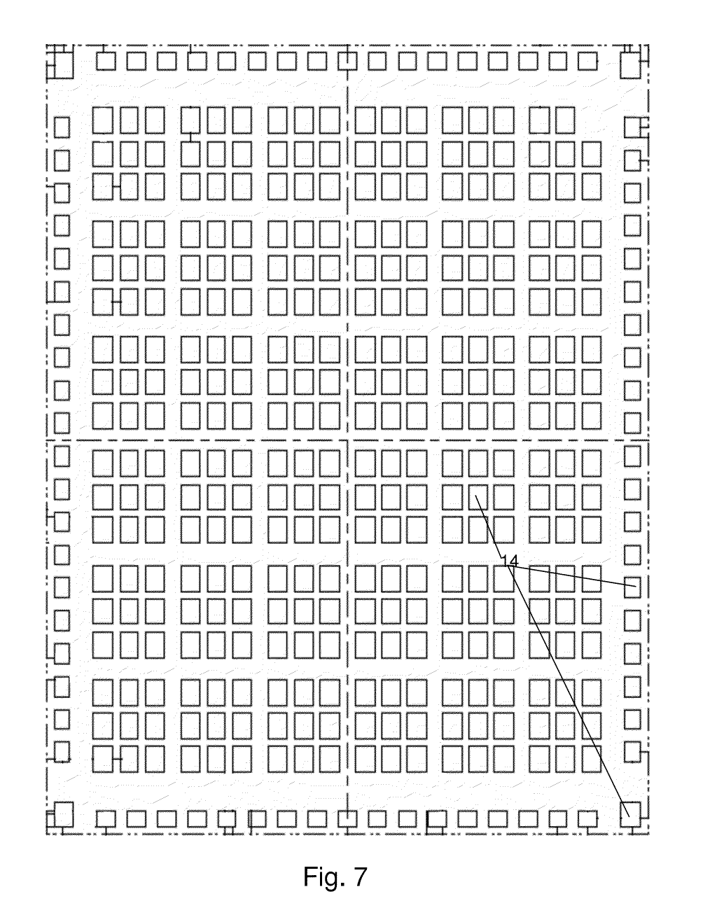

FIG. 6 shows a top view of a pattern 14 for applying soldering material, more specifically solder paste, onto the printed circuit board shown in FIG. 5. More specifically a stencil made on this basis can be used to apply soldering material, more specifically soldering material, to the further substrate, for the example the printed circuit board 16. As can be seen on FIG. 6, care has been taken to avoid application of soldering material onto the through-hole 12. However, when no through holes 12 are provided, for example because it is not feasible to provide through holes because the through holes would interfere with for example electric circuits in the printed circuit board, in the printed circuit board 16, a different pattern can be used for applying solder paste onto the printed circuit board 16 such as the pattern for example shown in FIG. 7 which also shows an improved escape of gasses resulting from the soldering.

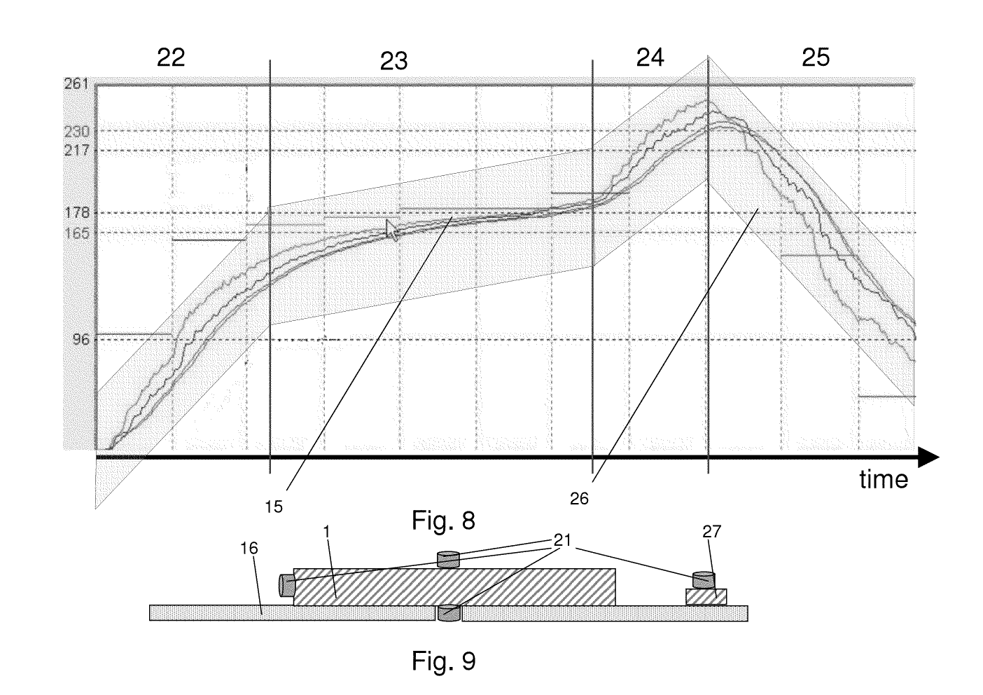

After application of the soldering material to the printed circuit board 16 and after mounting of the system in package 1 to the printed circuit board 16, with or without through holes 12, the soldering material needs to be heated in order to attach the system in package 1 to the printed circuit board 16. This process is usually known to the person skilled in the art as reflow. The reflow process preferably applies subsequent steps of heating or cooling to the assembly of the printed circuit board 16 with the system in package 1. This is for example illustrated in FIG. 8 in which the X-axis indicates the different steps applied, and in other words indicates time, and in which the Y-axis indicates the temperatures to which the assembly of printed circuit board 16 and system in package 1 are subjected. The curve 15 in other words indicates the temperature in function of time to which the assembly of the printed circuit board 16 and system in package 1 is subjected and are often called reflow profiles by the person skilled in the art. The different temperature curves 15 in FIG. 8 correspond to the temperature measurements on various locations of an assembly of a system in package 1 and a surface mounted device 27 mounted on a printed circuit board 16 by thermocouples 21 on predetermined locations as shown in FIG. 9. As known by the person skilled in the art the temperature curves 15 can be divided in four regions 22, 23, 24, 25: a preheat region 22, a soak zone 23, a reflow zone 24 and a cooling down zone 25. The soak zone 23 allows the flux to be activated such that the wetting characteristics of the solder material, preferably solder paste, are improved. In each zone each of the curves should be within a range 26, known by the person skilled in the art as the gabarit, indicated in the FIG. 8. The inventor has found that by keeping the rise of temperature in the soak zone 23 within a range of 7° C./min-15° C./min, more preferably 10° C./min, the escape of flux gasses resulting from the heating of the soldering material dramatically improves. The duration of the soak zone 23 should preferably be long enough to allow substantially all gasses formed by soldering to escape.

The inventor has also found that it is important in order to have a smooth rise in temperature in the soak zone 23 to start the soak zone at the flux activation temperature to get quick flux activation and will result in a better and more complete escape of flux gasses resulting from soldering, before entering the reflow zone 24. Alternatively, as to avoid thermal stress and to have complete escape of flux gasses, one can enter the soak zone at lower temperature and as compensation for example prolong the soak zone.

However the precise reflow profile 15 is not essential for the invention and can be further determined by the person skilled in the art depending on the specific printed circuit board 16 and the system in package 1 used.

1-14. (canceled)

15. Use of a system in package comprising a substrate having at least a first external layer comprising a first conductive patterned layer and being externally accessible for electrically connecting the system in package to an external electric circuit and a second internal layer comprising a second conductive patterned layer and being covered by the first layer and electronic devices provided on the substrate and electrically connected to external contact pads of the first conductive patterned layer, the devices and the first and the second conductive patterned layer being electrically connected such as to form an internal electric circuit provided to be electronically connected to the external electric circuit, the first and the second layer being adjacently positioned, the electronic devices being enclosed in an overmould compound, wherein at least one of the devices is electrically connected to at least one hidden contact pad of the second conductive patterned layer which is accessible after removal of a removable strip of the first layer, and wherein the strip is scratched away from, pulled away from, peeled off or chemically removed from the system in package.

16. System in package comprising a substrate having at least a first external layer comprising a first conductive patterned layer and being externally accessible for electrically connecting the system in package to an external electric circuit and a second internal layer comprising a second conductive patterned layer and being covered by the first layer and electronic devices provided on the substrate and electrically connected to external contact pads of the first conductive patterned layer, the devices and the first and the second conductive patterned layer being electrically connected such as to form an internal electric circuit provided to be electronically connected to the external electric circuit, the first and the second layer being adjacently positioned, the electronic devices being enclosed in an overmould compound, wherein at least one of the devices is electrically connected to at least one hidden contact pad of the second conductive patterned layer which is accessible after removal of a removable strip of the first layer, and wherein the strip is provided to be peeled off the system in package.

17. System in package according to claim 16, wherein the contact pads are conductive members provided to be in electrical contact with an external electric circuit and which are a conductive part of an electrically conductive path providing an electrical connection to one of the electronic devices of the system in package, the contact pad being located at an end part of the conductive path which is distal from an opposing end part of the conductive path providing an electrical connection to one of the electronic devices of the system in package.

18. System in package according to claim 16, wherein the thickness of the strip and the thickness of the first layer are the same.

19. System in package, according to claim 15, wherein the system in package is planar and in that the first layer is a top layer of the system in package.

20. System in package according to claim 15, wherein the hidden contact pad is a debugging pad.

21. System in package according to claim 15, wherein the removable strip is one of the external contact pads of the first layer having a different functionality from the hidden contact pad.

22. System in package according to claim 21, wherein at least one of the devices is electrically connected to an additional hidden contact pad of the second layer which is accessible after removal of the removable strip of the first layer, the additional hidden contact pad having the same functionality as the external contact pad of the removable strip.

23. System in package according to claim 15, wherein at least one of the external contact pads is a ground pad.

24. System in package according to claim 15, wherein at least one of the external contact pads is a soldering pad having a predetermined size for heat dissipation.

25. System in package according to claim 15, wherein at least one of the devices is an integrated circuit.

26. System in package according to claim 15, wherein the substrate is a land grid array substrate.

27. System in package according to claim 15, wherein the overmould compound is ceramic.

28. Printed circuit board comprising a printed circuit board substrate on which an electric circuit is provided electrically connected to a system in package according to claim 15.
